(19) United States
(12) Patent Application Publication
(10) Pub. No.: US 2025/0385697 A1
(43) Pub. Date: Dec. 18, 2025

(54) RECONFIGURABLE MULTI-FEEDBACK FILTER FOR MMW RECEIVERS

(71) Applicant: QUALCOMM Incorporated, San Diego, CA (US)

(72) Inventors: Rahul SINGH, San Diego, CA (US); Jeremy GOLDBLATT, Encinitas, CA (US); Ahmed ABBAS MOHAMED HELMY, San Diego, CA (US)

(21) Appl. No.: 18/747,384

(22) Filed: Jun. 18, 2024

(51) Int. Cl. H04B 1/00; H04B 1/10

(52) U.S. Cl. CPC H04B 1/0078; H04B 1/1018

(57) ABSTRACT

Aspects described herein include devices and methods for a reconfigurable multi-feedback filter for wireless receivers. In one aspect, a device may include a signal input node, a signal output, and an amplifier having an amplifier output, a negative input, and a positive input. The positive input is coupled to a reference voltage, and the amplifier output is coupled to the signal output. The device may further include a twin-T network in a feedback path coupled from the amplifier output to the negative input, where the twin-T network comprises a first capacitor and a second capacitor serially coupled between the amplifier output and the negative input of the amplifier, where the first capacitor and the second capacitor are connected via a first node, and where the signal input node is coupled to the first node.

### FIELD

The present disclosure relates generally to electronics and wireless communications. For example, aspects of the present disclosure relate to receive circuitry for millimeter wave wireless receivers.

### BACKGROUND

Wireless communication devices and technologies are becoming ever more prevalent. Wireless communication devices generally transmit and receive communication signals. Radio frequency front end (RFFE) modules are wireless communication apparatuses that power wireless transmit signals, and can also manage reception of wireless signals from an antenna at high frequencies (e.g., radio frequency, millimeter wave frequency, etc.) Wireless signals can be downconverted in receive paths of a wireless communication device to baseband signals. For higher frequency communication bands, the bandwidths of communication bands can be large, with associated complexity in signal processing. Limiting power usage and managing power efficiency is an important goal of device design, particularly for mobile devices, and increasingly complex systems which integrate millimeter wave technology into mobile devices that can be used for communications and/or for radar applications.

### SUMMARY

Various implementations of systems, methods, and devices within the scope of the appended claims each have several aspects, no single one of which is solely responsible for the desirable attributes described herein. Without limiting the scope of the appended claims, some prominent features are described herein.

In some aspects, the techniques described herein relate to a filter apparatus including: a signal input node; a signal output; an amplifier having an amplifier output, a negative input, and a positive input, wherein the positive input is coupled to a reference voltage, and wherein the amplifier output is coupled to the signal output; and a twin-T network in a feedback path coupled from the amplifier output to the negative input, wherein the twin-T network includes a first capacitor and a second capacitor serially coupled between the amplifier output and the negative input of the amplifier, wherein the first capacitor and the second capacitor are connected via a first node, and wherein the signal input node is coupled to the first node.

In some aspects, the techniques described herein relate to a filter apparatus, wherein the twin-T network further includes: a first resistor and a second resistor serially coupled between the amplifier output and the negative input of the amplifier, wherein the first resistor and the second resistor are connected via a second node, wherein the signal input node is coupled to the second node, and wherein the second node is coupled to a reference node via a third capacitor.

In some aspects, the techniques described herein relate to a filter apparatus, wherein the signal input node is coupled to the first node via a third capacitor, wherein the signal input node is coupled to the second node via a third resistor, and wherein the second node is coupled to a reference node via a fourth capacitor.

In some aspects, the techniques described herein relate to a filter apparatus, further including a fourth resistor coupled in parallel across the first capacitor.

In some aspects, the techniques described herein relate to a filter apparatus, further including high frequency real pole circuitry coupled to the signal input node.

In some aspects, the techniques described herein relate to a filter apparatus, wherein the high frequency real pole circuitry includes: a fifth resistor coupled between a second input node and the signal input node; a fifth capacitor coupled between the signal input node and the reference node; and the fourth capacitor.

In some aspects, the techniques described herein relate to a filter apparatus, further including a plurality of switches in the feedback path configurable for multiple operational configurations.

In some aspects, the techniques described herein relate to a filter apparatus, wherein the multiple operational configurations include a Rauch filter configuration and a Rauch filter with a transmission zero filter configuration.

In some aspects, the techniques described herein relate to a filter apparatus, wherein the multiple operational configurations further include a programmable gain amplifier (PGA) configuration.

In some aspects, the techniques described herein relate to a filter apparatus, wherein the plurality of switches include: a first switch coupled between the signal input node and the third capacitor; a second switch coupled between the signal input node and the fifth resistor; a third switch coupled between the fourth capacitor and a node between the second resistor and the third resistor; a fourth switch coupled between the first resistor and the node between the second resistor and the third resistor; a fifth switch coupled between the negative input and the second capacitor; a sixth switch coupled between the second capacitor and the fourth resistor; a seventh switch coupled between the negative input and the fourth resistor; an eighth switch coupled between the second capacitor and the first capacitor; and a ninth switch coupled between the negative input and the first capacitor.

In some aspects, the techniques described herein relate to a filter apparatus, wherein control circuitry coupled to the plurality of switches closes the second switch, seventh switch, and the ninth switch, and opens the first, third, fourth, fifth, sixth, and eighth switches for the PGA configuration.

In some aspects, the techniques described herein relate to a filter apparatus, wherein the control circuitry closes the third, fourth, and ninth switches and opens the first, second, third, fifth, sixth, seventh, and eighth switches for the Rauch filter configuration.

In some aspects, the techniques described herein relate to a filter apparatus, wherein the control circuitry closes the first, third fourth, fifth, seventh, and ninth switches and opens the second, sixth, and eighth switches for the Rauch filter with the transmission zero filter configuration.

In some aspects, the techniques described herein relate to a filter apparatus, further including high frequency real pole circuitry coupled to the signal input node.

In some aspects, the techniques described herein relate to a filter apparatus, wherein the high frequency real pole circuitry includes: an input resistor coupled between a second input node and the signal input node; a fifth capacitor coupled between the signal input node and the reference node; and the fourth capacitor.

In some aspects, the techniques described herein relate to a filter apparatus, wherein the plurality of switches further includes a tenth switch coupled between the fifth capacitor and the signal input node, wherein the tenth switch enables and disables the high frequency real pole circuitry.

In some aspects, the techniques described herein relate to a filter apparatus, wherein the filter apparatus includes a baseband filter in a receive signal path for a downconverted millimeter wave (mmW) signal.

In some aspects, the techniques described herein relate to a filter apparatus including: means for filtering a baseband signal in a receive signal path for a downconverted millimeter wave signal; and means for suppressing an aliasing signal generated by a low clock-rate analog to digital converter in the receive signal path of a multi-downlink pipe (DLP) receiver of a millimeter wave communication device.

In some aspects, the techniques described herein relate to a method of operating a wireless communication device, the method including: receiving a wireless millimeter wave communication signal; downconverting the wireless millimeter wave communication signal to a baseband communication signal; filtering the baseband communication signal using a filter apparatus including a twin-T network in a feedback path with notch rejection at aliasing frequencies associated with a low clock-rate analog to digital converter to generate a filtered baseband communication signal; and converting the filtered baseband communication signal to a digital signal using the low clock-rate analog to digital converter.

In some aspects, the techniques described herein relate to a method, wherein the twin-T network further includes: a first resistor and a second resistor serially coupled between the amplifier output and the negative input of the amplifier, wherein the first resistor and the second resistor are connected via a second node, wherein the signal input node is coupled to the second node, and wherein the second node is coupled to a reference node via a third capacitor.

In some aspects, the apparatuses described above can function in a system that includes a mobile device with a camera for capturing one or more pictures. In some aspects, the apparatuses described above can include a display screen for displaying one or more images or interface displays. In some aspects, additional wireless communication circuitry is provided. The summary is not intended to identify key or essential features of the claimed subject matter, nor is it intended to be used in isolation to determine the scope of the claimed subject matter. The subject matter should be understood by reference to appropriate portions of the entire specification, any or all drawings, and each claim.

The foregoing, together with other features and embodiments, will become more apparent upon referring to the following specification, claims, and accompanying drawings.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless communication system communicating with a wireless device that can be implemented according to aspects described herein.

FIG. 2A is a block diagram showing a device including a multi-downlink pipe (DLP) receiver for millimeter wave (mmW) communication in accordance with aspects described herein.

FIG. 2B is a chart illustrating aspects of signals in a multi-DLP receiver for mmW communication in accordance with aspects described herein.

FIG. 2C is a block diagram showing a device including an alternate receiver configuration in accordance with aspects described herein.

FIG. 3 illustrates aspects of a filter for use within a multi-DLP receiver for mmW communication in accordance with aspects described herein.

FIG. 4 illustrates aspects of a reconfigurable filter for use in a multi-DLP receiver for mmW communication in accordance with aspects described herein.

FIG. 5 illustrates aspects of one configuration of a reconfigurable filter for use in a multi-DLP receiver for mmW communication in accordance with aspects described herein.

FIG. 6 illustrates aspects of one configuration of a reconfigurable filter for use in a multi-DLP receiver for mmW communication in accordance with aspects described herein.

FIG. 7 illustrates aspects of one configuration of a reconfigurable filter for use in a multi-DLP receiver for mmW communication in accordance with aspects described herein.

FIG. 8 illustrates aspects of a reconfigurable filter with a high frequency real pole at the input for use within a multi-DLP receiver for mmW communication in accordance with aspects described herein.

FIG. 9 is a flow diagram illustrating aspects of a method in accordance with aspects described herein.

FIG. 10 is a functional block diagram of an apparatus in accordance with some aspects of the present disclosure.

FIG. 11 is a diagram illustrating an environment that includes an electronic device and a base station that can be used with aspects of the present disclosure.

FIG. 12 is a diagram of an electronic device that can be used with aspects of the present disclosure.

### DETAILED DESCRIPTION

The detailed description set forth below in connection with the appended drawings is intended as a description of example aspects and implementations and is not intended to represent the only implementations in which the invention may be practiced. The detailed description includes specific details for the purpose of providing a thorough understanding of the example aspects and implementations. In some instances, some devices are shown in block diagram form. Drawing elements that are common among the following figures may be identified using the same reference numerals.

The progression of wireless communication infrastructure, such as for Third Generation Partnership Project (3GPP) fifth generation (5G) millimeter wavelength (mmW) systems, involves increasing importance of power management. For example, 5G standards for cellular communications involve increasing complexity of frequency combinations and communication throughput options. Further, with communications systems extending into higher frequencies, including millimeter wave (mmW) frequencies, additional functions such as radar applications for local object detection, 3D mapping, positioning, gesture detection, and other such applications. Limiting power usage and managing power efficiency is an important goal of device design, particularly for mobile devices.

One option for power reduction in a wireless communication device is minimizing the sampling frequency of analog to digital (ADC) converters used in a receive path. For receiver designs in a multi-downlink pipe (DLP) system, the use of a low sampling frequency ADC converter can result in aliasing signals that can interfere with communication signals. Aspects described herein include filter apparatus including notch rejection at aliasing frequencies associated with the low sampling frequencies in such a system used for power reduction.

In some aspects, a reconfigurable design with switches can be used to allow flexibility in a receive path filter. In other aspects, a simplified design without switches can be used to minimize filter complexity and maximize performance. Details of various implementations are provided below.

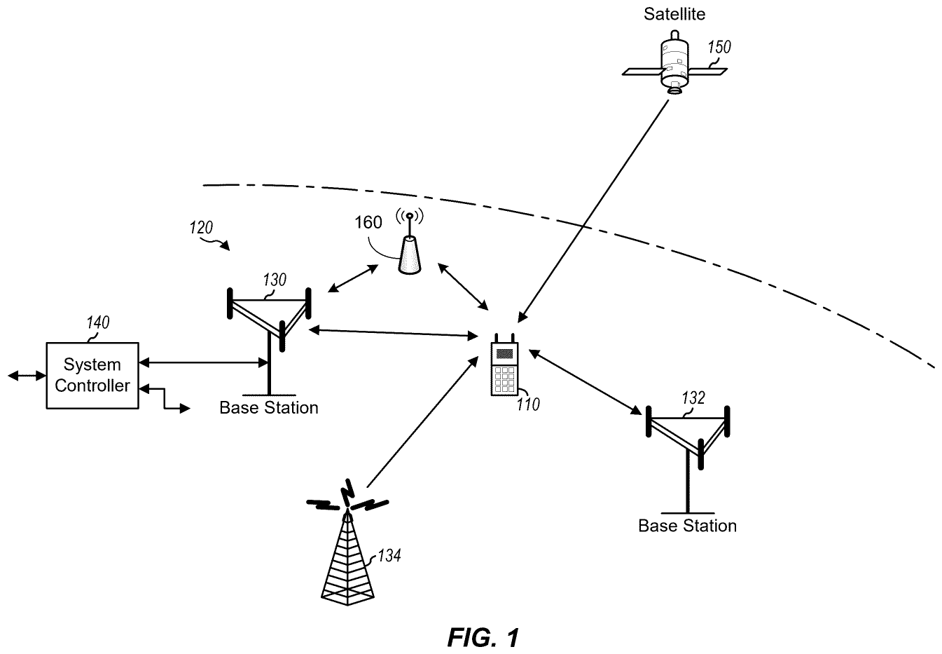

FIG. 1 is a diagram showing a wireless device 110 communicating with a wireless communication system 120. In accordance with aspects described herein, the wireless device can include electronic devices with wireless communication capabilities enabled by a multi-DLP receive system in accordance with aspects described herein.

The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. Communication elements of the wireless device 110 for implementing mmW and non-mmW communications in accordance with any such communication standards can be supported by various designs of transceivers. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, or other such mobile device (e.g., a device integrated with a display screen). Other examples of the wireless device 110 include a wireless modem, a personal digital assistant (PDA), a handheld device, a laptop computer, a smartbook, a netbook, a tablet, a cordless phone, a medical device, a device configured to connect to one or more other devices (for example through the internet of things), an automobile or other automotive device, a wireless local loop (WLL) station, a Bluetooth device, etc. Wireless device 110 may communicate with wireless communication system 120. Wireless device 110 may also receive signals from broadcast stations (e.g., a broadcast station 134) and/or communicate with satellites (e.g., a satellite 150 in one or more global navigation satellite systems (GNSS), etc.). Wireless device 110 may support one or more radio technologies for wireless communication such as LTE, WCDMA, CDMA 1X, EVDO, TD-SCDMA, GSM, 802.11, 5G, etc.

The wireless communication system 120 may also include a wireless device 160. In an exemplary embodiment, the wireless device 160 may be a wireless access point, or another wireless communication device that comprises, or comprises part of a wireless local area network (WLAN). In an exemplary embodiment, the wireless device 110 may be configured as a customer premises equipment (CPE), which may be in communication with a base station 130 and another wireless device 110, or other devices in the wireless communication system 120. In some embodiments, the CPE may be configured to communicate with the wireless device 160 using WAN signaling and to interface with the base station 130 based on such communication instead of the wireless device 160 directly communicating with the base station 130. In exemplary embodiments where the wireless device 160 is configured to communicate using WLAN signaling, a WLAN signal may include WiFi, or other communication signals.

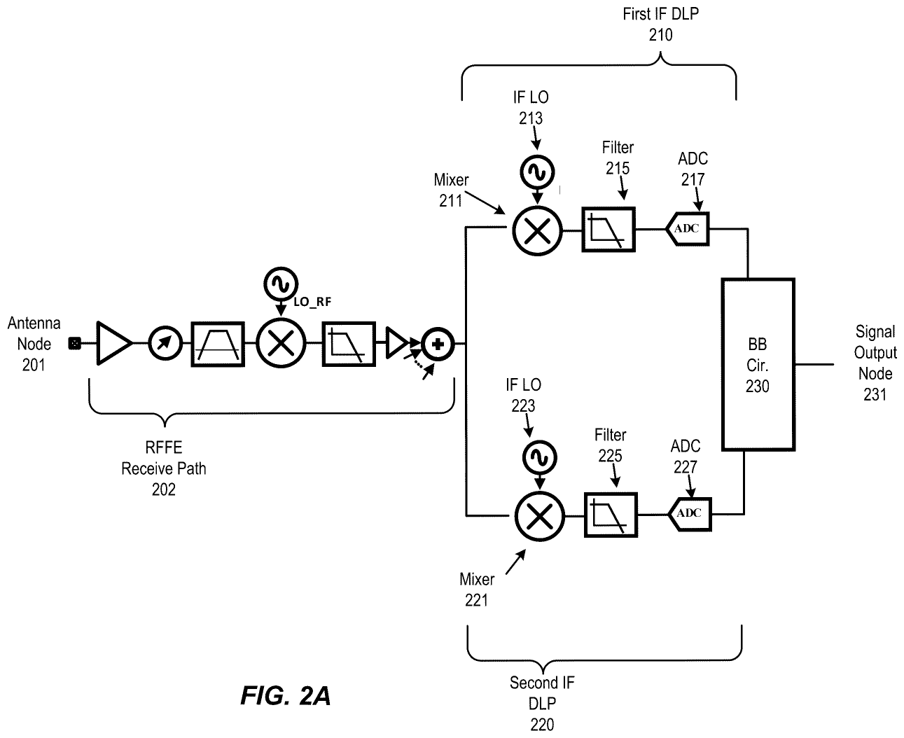

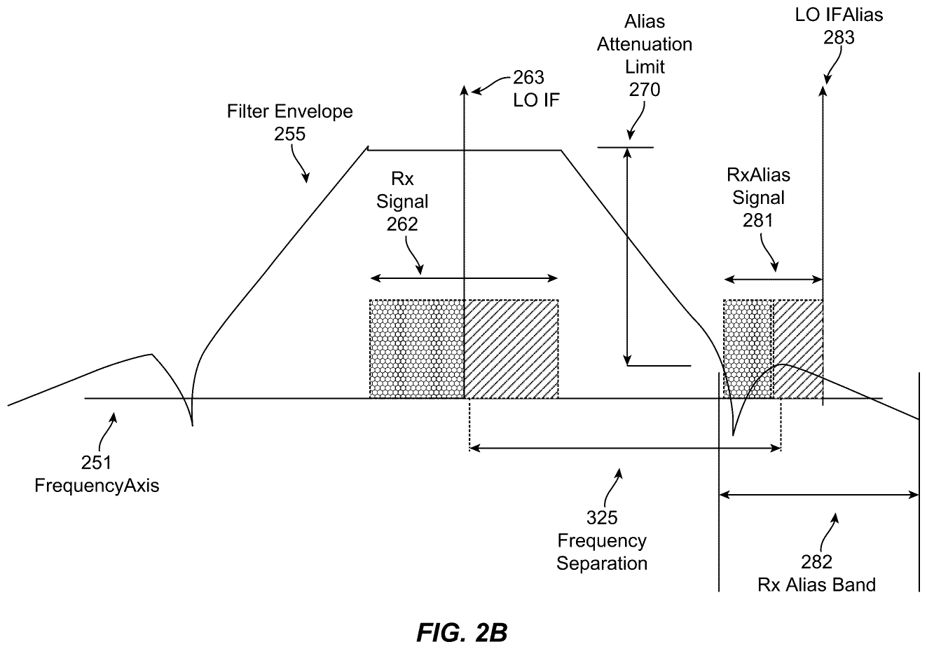

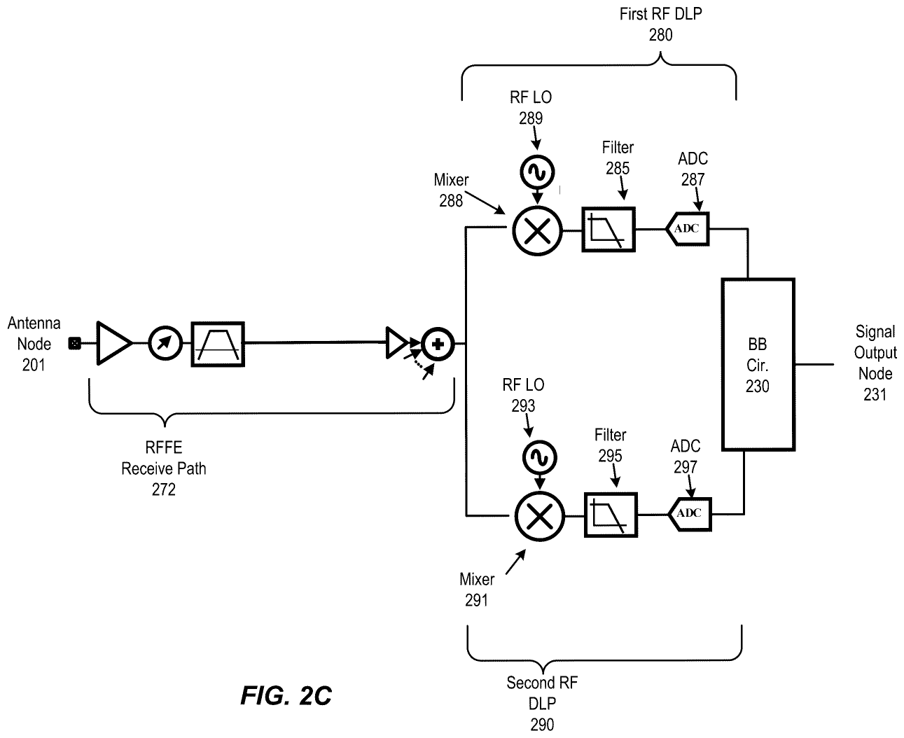

FIG. 2A is a block diagram showing a device including a multi-downlink path (DLP) receiver for millimeter wave (mmW) communication in accordance with aspects described herein. FIG. 2A shows an example of a receiver having a receive path that receives a wireless communication signal (e.g., a mmW communication signal) from an antenna node 201. A single RF front end receive path 202 is shown, but multiple RFFE receive paths can be present that are coupled to intermediate frequency (IF) DLPs 210 and 220 at the end of each receive path as shown by the elements of the receive path 202. The illustrated RFFE receive path 202 includes an attenuator, a bandpass filter, a mixer, a low pass filter, an amplifier, and circuitry to couple signals from multiple receive paths. Each of these path elements may be single-ended or differential.

The receiver may be coupled to an antenna via the illustrated antenna node 201. The antenna is configured to receive a wireless signal (e.g., from a base station, a wireless access point, another wireless device, etc.). In one example, the receiver may be integrated on a chip and coupled to the antenna (e.g., off-chip antenna) via receive pins. The RF signal may be a differential signal or a single-ended signal. In certain aspects, the receive pins may be coupled to the antenna via a transformer (not shown) configured to convert a singled-ended RF signal from the antenna into a differential RF signal at the receive pins. The antenna may be single-ended or differential. Other implementations of a receiver or RFFE receive paths can include alternate configurations of receive path elements.

In the illustrated aspect of FIG. 2A, the signal (e.g., mmW signal) is downconverted to an IF frequency in the RFFE receive path 202, and can be provided to a first IF DLP 210 or a second IF DLP 220. Each IF DLP 210, 220 includes a mixer 211, 221 and LO 213, 223 for further downconverting an IF signal to a baseband signal. The IF DLPs 210, 220 then include baseband filters 215, 225, analog to digital converters 217, 227 respectively, which output digital signals to baseband circuitry 230 which can then provide the data received to additional control or processing circuitry of a device. Filters described below in accordance with aspects described herein can be used for filters such as the filter 215 and the filter 225.

The illustrated system with two IF DLPs 210, 220 can be used to avoid a design and power burden associated with high bandwidth and ADC sampling rates when a single DLP design is used. The multi-DLP design has advantages for intra-band carrier aggregation (CA) of communication signals, including a reduction in the bandwidth needed from the baseband filters 215, 225. In some aspects, this also provides a benefit with sub-6 gigahertz (GHz) and mmW-IF signal convergence, where a sub-6 GHz communication band DLP can be reused as a mmW-IF DLP. Further, the sampling rates of the ADCs 217, 227 can be reduced, limiting ADC design complexity and reducing power usage of the ADCs. A reduced ADC sampling rate, while limiting power usage, can create issues with baseband signal aliasing as illustrated below.

FIG. 2B is a chart illustrating aspects of signals in a multi-downlink pipe (DLP) receiver for millimeter wave (mmW) communication in accordance with aspects described herein. FIG. 2B illustrates a frequency band with the x-axis representing frequency as a frequency axis 251, and the y axis representing a signal amplitude (e.g., for the LO IF 263 signal) or a gain value (e.g., for the filter envelope 255). As shown, the filter envelope includes a passband filter in a frequency band covering an Rx signal 262 and the LO IF 263 signal. The multi-DLP circuitry of the system described by FIG. 2A can result in aliasing, resulting in an Rx alias signal 281 and a LO IF alias 283 signal in an Rx alias Band 282 separated from the receive signals by a frequency separation 325. The filter envelope 255 is designed not only to operate as a passband for the Rx signal 262 and the LO IF 263 signal, but to exceed an alias attenuation limit 270 for alias signals in the Rx alias band 282 (e.g., the LO IF alias 283 signal and the Rx alias signal 281).

FIG. 2C illustrates an alternate implementation of a receiver in accordance with some aspects described herein. The receiver of FIG. 2C is similar to the receiver of FIG. 2A, but with the dual conversion eliminated. Such an aspect includes the antenna node 201, but with an alternate RFFE receive path 272 that does not include an intermediate frequency downconversion. Instead, the transmission signal is split into two radio frequency downlink pipes (RF DLPs) 280 and 282. Similar to the system of FIG. 2A, the two DLPs 280, 290 each include corresponding mixers 288, 291, RF LOs 289, 293, filter 285, 295, and ADCs 287, 297, with digital output signals provided to the signal output node 231 from the baseband circuitry 230. Such an aspect can be used for wideband signal processing such as new fifth generation bands (e.g., B77, B46, etc.). While various aspects described herein particularly recite mmW signals, implementations of various aspects described herein, including the receivers of FIGS. 2A and 2C, can be used for processing other signals or wide bands in other implementations.

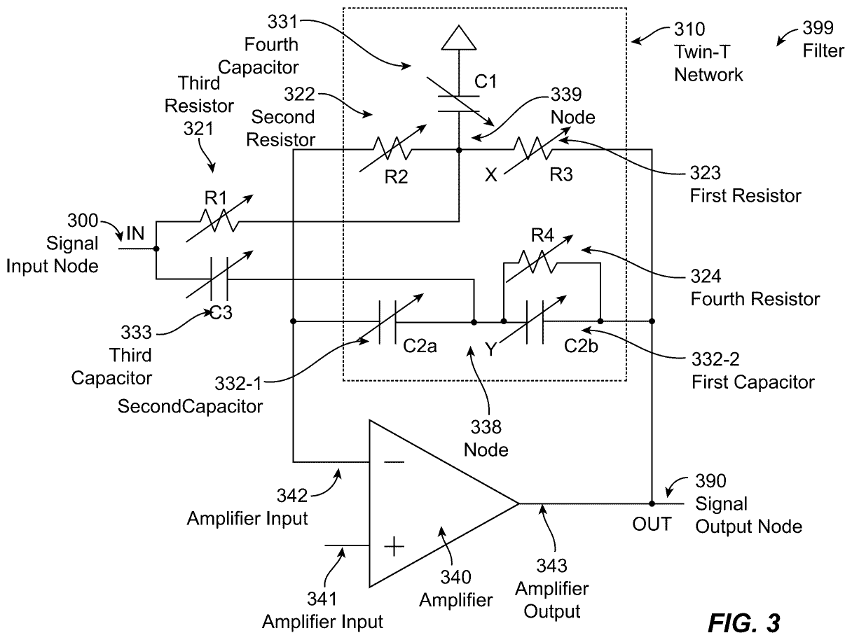

FIG. 3 illustrates aspects of a filter 399 for use within a multi-downlink pipe (DLP) receiver for millimeter wave (mmW) communication in accordance with aspects described herein. The filter 399 includes a twin-T network in a feedback path of the filter 399 (e.g., the feedback path from the amplifier output 343 back to the negative amplifier input 342). The filter 399 includes a signal input node 300, a signal output node 231, an amplifier 340 having an amplifier output 343, a negative input 342, and a positive input 341. The positive input 341 is coupled to a reference voltage (e.g., ground), and the amplifier output 343 is coupled to the signal output 390. In some aspects, the twin-T network 310 in the feedback path is coupled from the amplifier output 343 to the negative input 342 via a first capacitor 332-2 and a second capacitor 332-1. The capacitors 332-1 and 332-2 are serially coupled between the amplifier output 343 and the negative input of the amplifier 340. The first capacitor 332-2 and the second capacitor 332-1 are connected via a first node 338, and the signal input node 300 is coupled to the first node 338.

In the illustrated filter 399, the twin-T network 310 further includes a first resistor 323 and a second resistor 322 serially coupled between the amplifier output 343 and the negative input 342 of the amplifier 340. The first resistor 323 and the second resistor 322 are connected via a second node 339, and the signal input node 300 is further coupled to the second node 339, with the second node further coupled to the reference node via a fourth capacitor 331. Additionally, as illustrated, the signal input node 300 is coupled to the first node 338 via a third capacitor 333, and the signal input node 300 is coupled to the second node 339 via a third resistor 321. The second node 339 is then coupled to a reference node (e.g., ground) via a fourth capacitor 331.

In some aspects, the fourth resistor 324 is optional. The fourth resistor can be omitted, leaving the position of the fourth resistor 324 open. In other aspects, the fourth resistor 324 can be present to increase the rejection of the notch to improve the suppression of the aliasing signal as detailed above in FIG. 2B. The filter 399 of FIG. 3 provides a filter with a transmission zero notch in the transition stop band. Such a notch is close to an edge of a first ADC alias band where a rejection from the filter order is least effective, but sufficient to provide a sufficient filter rejection (e.g., the filter rejection of the alias attenuation limit 270) to allow adequate performance and suppression of an alternate carrier signal in a carrier aggregation environment with multiple-DLP as illustrated in FIG. 2A. Aspects described herein improve on prior filters with removal or repositioning of resistive elements coupled to the capacitors 322-1 and 332-2 (e.g., placement or omission of the fourth resistor 324) to improve rejection of the notch element at the targeted aliasing frequencies.

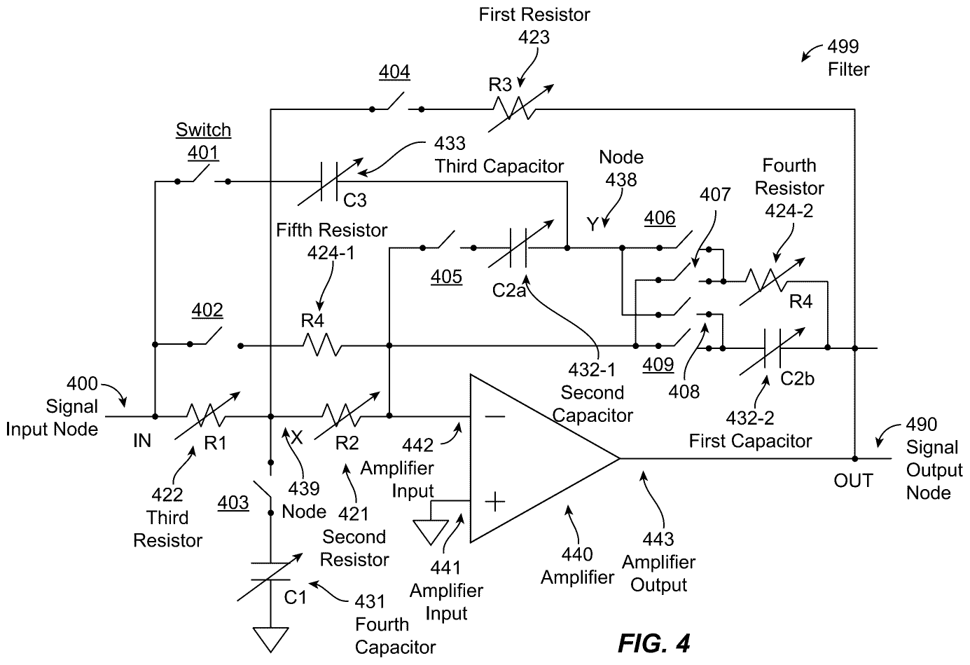

FIG. 4 illustrates aspects of a reconfigurable filter 499 for use within a multi-downlink pipe (DLP) receiver for millimeter wave (mmW) communication in accordance with aspects described herein. The reconfigurable filter 499 includes the same elements as the filter 399, but reconfigured with added switches 401, 402, 403, 404, 405, 406, 407, 408, and 409 to allow configuration in multiple operating configurations as detailed below.

The described elements of the reconfigurable filter 499 are functionally the same as elements of the filter 399 (e.g., first capacitor 432-2 corresponds to the first capacitor 332-2, first resistor 423 corresponds to the first resistor 323, etc.), positioned in a different layout to simplify the presentation of the switches included in the reconfigurable filter 499.

As illustrated, the reconfigurable filter 499 includes a signal input node 400, a signal output node 490, an amplifier 440 having an amplifier output 443, a negative input 442, and a positive input 441. The positive input 441 is coupled to a reference voltage (e.g., ground), and the amplifier output 443 is coupled to the signal output node 490. The feedback path is coupled from the amplifier output 443 to the negative input 442 via a first capacitor 432-2 and a second capacitor 432-1. The capacitors 432-1 and 432-2 are serially coupled between the amplifier output 443 and the negative input of the amplifier 440. The first capacitor 432-2 and the second capacitor 432-1 are connected via a first node 438, and the signal input node 400 is coupled to the first node 438.

In the illustrated filter 499, a first resistor 423 and a second resistor 422 are serially coupled between the amplifier output 443 and the negative input 442 of the amplifier 440. The first resistor 423 and the second resistor 422 are connected via a second node 439, and the signal input node 400 is further coupled to the second node 439, with the second node further coupled to the reference node via a fourth capacitor 431. Additionally, as illustrated, the signal input node 400 is coupled to the first node 438 via a third capacitor 433, and the signal input node 400 is coupled to the second node 439 via a third resistor 421. The second node 439 is then coupled to a reference node (e.g., ground) via a fourth capacitor 431.

In some aspects, the fourth resistor 424-2 is optional. The fourth resistor can be omitted, leaving the position of the fourth resistor 424-2 open. In other aspects, the fourth resistor 424-2 can be present to increase the rejection of the notch to improve the suppression of the aliasing signal as detailed above in FIG. 2B.

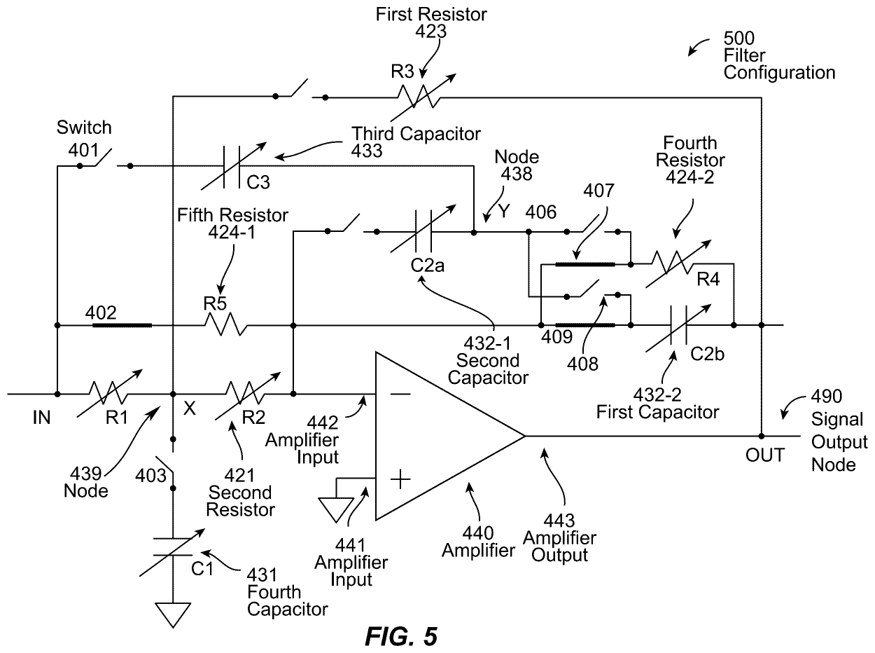

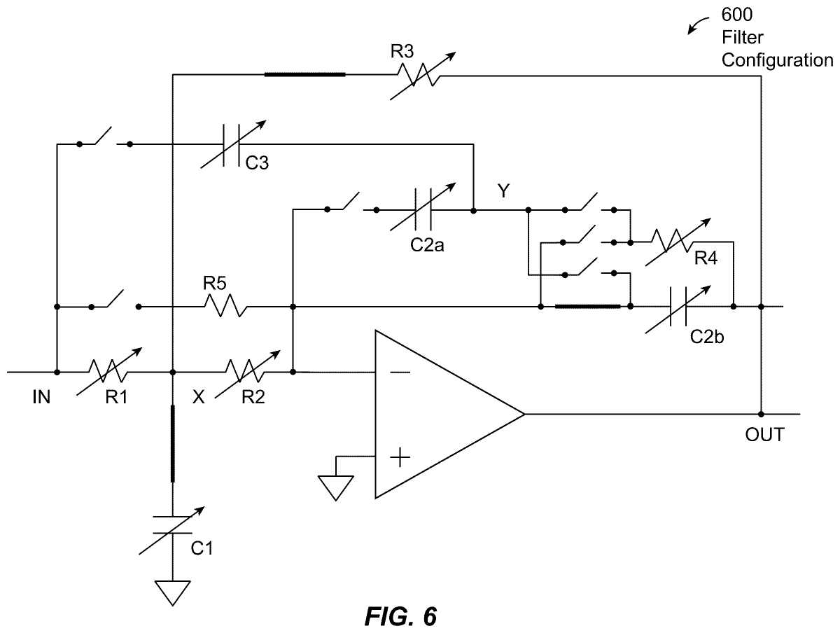

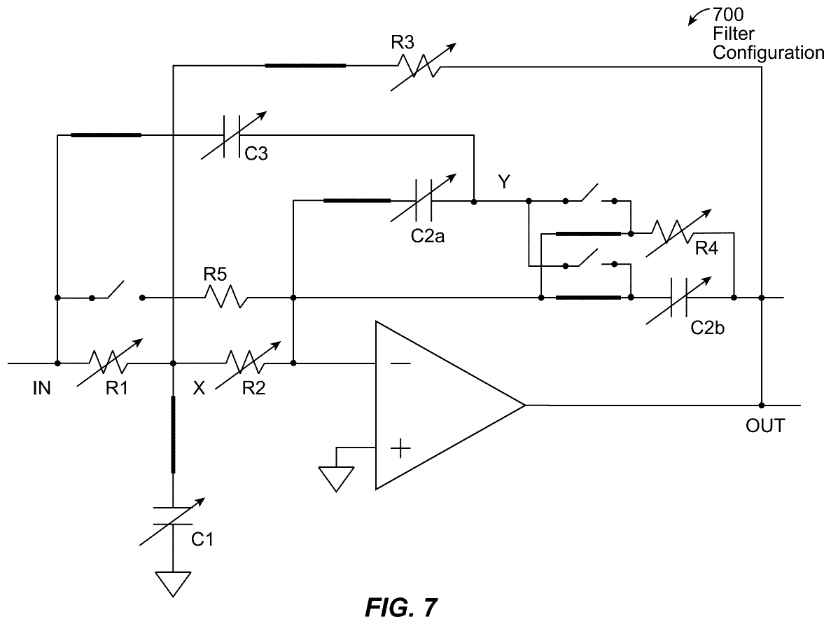

As illustrated, the filter 499 then further includes switches to allow multiple operating configurations. As illustrated, three operating configurations are possible with the provided switches, a programmable gain amplifier operating mode (e.g., illustrated in FIG. 5), a Rauch operating mode (e.g., illustrated in FIG. 6), and a Rauch operating mode with a transmission zero (e.g., illustrated in FIG. 7). The addition of the switches allows for varying filter and gain performance for different communication bands that share a downlink pipe in a multi-DLP architecture.

As shown, the reconfigurable filter 499 includes a first switch 401 coupled between the signal input node 400 and the third capacitor 433. The reconfigurable filter 499 includes a second switch 402 coupled between the signal input node 400 and the fifth resistor 424-1. The reconfigurable filter 499 includes a third switch 403 coupled between the fourth capacitor 431 and a node between the second resistor 422 and the third resistor 421. The reconfigurable filter 499 includes a fourth switch 404 coupled between the first resistor 423 and the node between the second resistor 422 and the third resistor 421. The reconfigurable filter 499 includes a fifth switch 405 coupled between the negative amplifier input 442 and the second capacitor 432-1. The reconfigurable filter 499 includes a sixth switch 406 coupled between the second capacitor 432-1 and the fourth resistor 424-2. The reconfigurable filter 499 includes a seventh switch 407 coupled between the negative amplifier input 442 and the fourth resistor 424-2. The reconfigurable filter 499 includes an eighth switch 408 coupled between the second capacitor 432-1 and the first capacitor 432-2. The reconfigurable filter 499 includes a ninth switch 409 coupled between the negative amplifier input 442 and the first capacitor 432-2.

FIG. 5 illustrates aspects of one configuration 500 of the reconfigurable filter 499 for use within a multi-DLP receiver for mmW communication in accordance with aspects described herein. In the configurations 500, 600, and 700, control circuitry (e.g., processor 1108, microprocessor 1212, or control circuitry of another such element such as modem 1218, transceiver 1122, etc.) can be used to set the closed or open position setting of the resistors of the reconfigurable filter 499. In the configuration 500, a PGA configuration is set. Control circuitry coupled to the plurality of switches closes the second switch 402, seventh switch, 407, and the ninth switch 409, and opens the first, third, fourth, fifth, sixth, and eighth switches 401, 403, 404, 405, 406, and 408 respectively for the PGA configuration.

FIG. 6 illustrates aspects of one configuration 600 of a reconfigurable filter 499 for use within a multi-DLP receiver for mmW communication in accordance with aspects described herein. Similar to the configuration 500 above, but with alternate switch settings, configuration 600 sets a Rauch filter configuration. For configuration 600, the control circuitry closes the third, fourth, and ninth switches 403, 404, and 409 and opens the first, second, third, fifth, sixth, seventh, and eighth switches 401, 402, 403, 405, 406, 407, and 408 for the Rauch filter configuration.

FIG. 7 illustrates aspects of one configuration 700 of a reconfigurable filter 499 for use within a multi-DLP receiver for mmW communication in accordance with aspects described herein. Configuration 700 sets a Rauch filter with transmission zero configuration. For configuration 700 the control circuitry closes the first, third, fourth, fifth, seventh, and ninth switches 701, 703, 704, 705, 707, 709 and opens the second, sixth, and eighth switches 702, 706, and 708 for the Rauch filter with the transmission zero filter configuration.

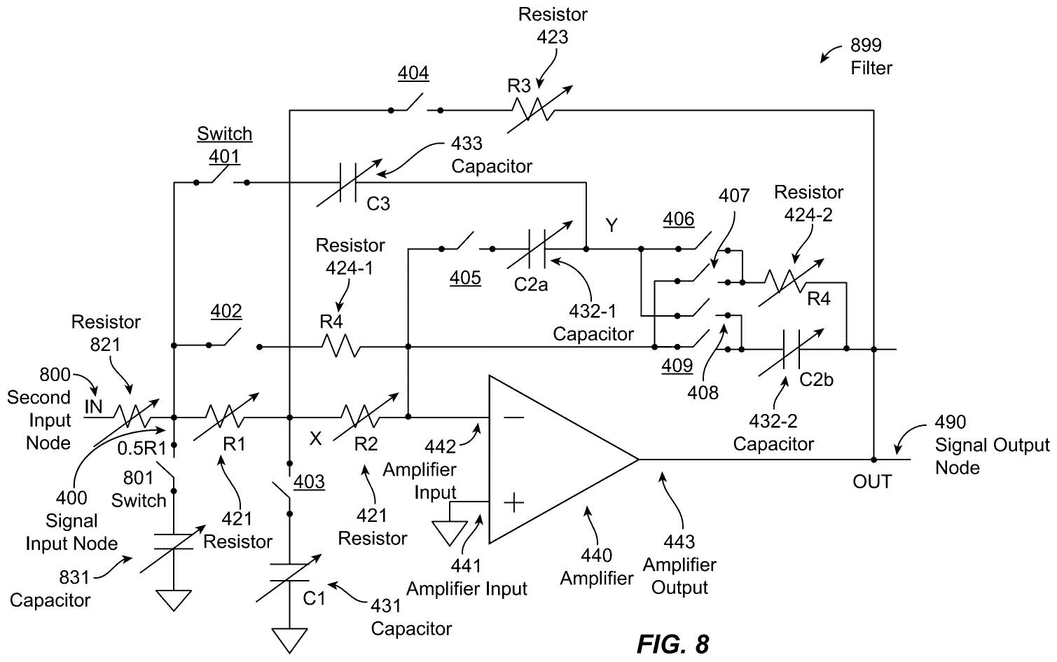

FIG. 8 illustrates aspects of a reconfigurable filter 899 with a high frequency real pole at the input for use within a multi-DLP receiver for mmW communication in accordance with aspects described herein. The reconfigurable filter 899 matches the reconfigurable filter 499, with added circuitry for a high frequency real pole at the signal input node 400 to improve notch rejection of aliasing frequencies as detailed above. The high frequency real pole circuitry includes an added input resistor as fifth resistor 821 coupled between a second input node 800 and the signal input node 400, a fifth capacitor 831 coupled between the signal input node 400 and the reference node as shown. and the fourth capacitor 431 via a switch 801. In additional aspects, such added circuitry can be added in the same configuration to the filter 399 to achieve an additional notch rejection of aliasing frequencies in accordance with aspects described herein. The elements of the high frequency pole are designed to place the pole close to, but after, the complex zero frequency to reduce passband sidelobes at frequencies just above the added notch frequencies. The fifth resistor 821 operates as a split value of the resistor 421 in the design of the reconfigurable filter 499 to reduce overhead, and the value of the added capacitor 831 is also small, limiting space overhead associated with the high frequency pole.

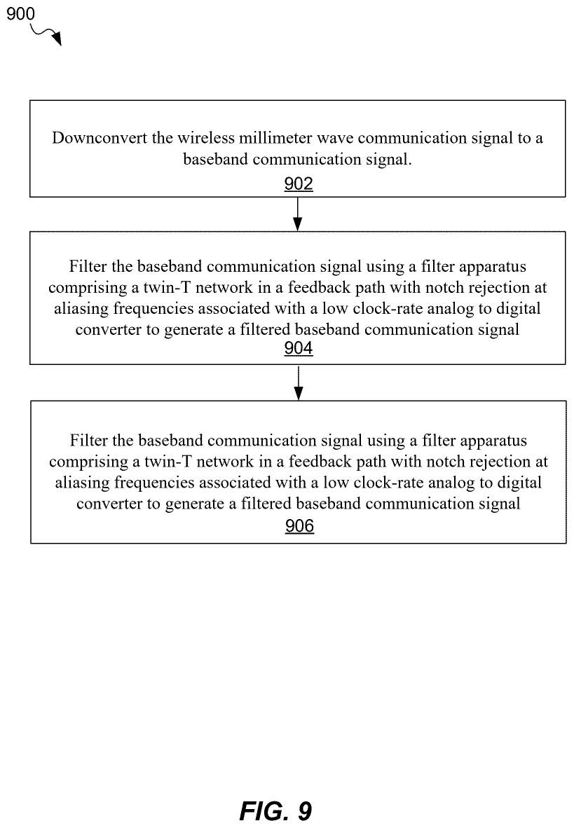

FIG. 9 is a flow diagram describing an example of the operation of a method 900 for operation of a device including a receiver system in accordance with aspects described herein. The blocks in the method 900 can be performed in or out of the order shown, and in some embodiments, can be performed at least in part in parallel.

The method 900 includes the block 902, which describes downconverting the wireless millimeter wave communication signal to a baseband communication signal.

The method 900 includes the block 904, which describes filtering the baseband communication signal using a filter apparatus comprising a twin-T network in a feedback path with notch rejection at aliasing frequencies associated with a low clock-rate analog to digital converter to generate a filtered baseband communication signal.

The method 900 includes the block 906, which describes converting the filtered baseband communication signal to a digital signal using the low clock-rate analog to digital converter.

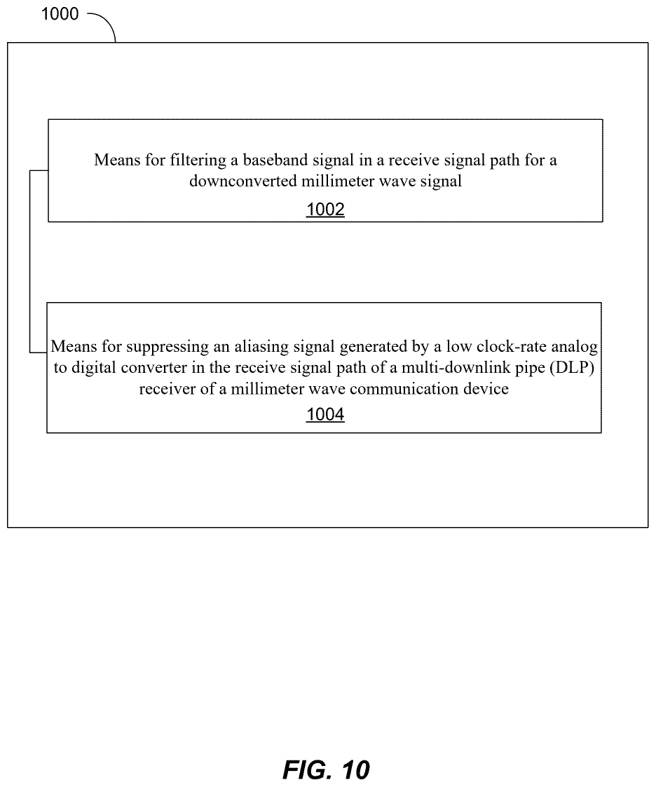

FIG. 10 is a functional block diagram of an apparatus 1000 including an architecture with a receiver system in accordance with aspects described herein. The apparatus 1000 comprises means 1002 for filtering a baseband signal in a receive signal path for a downconverted millimeter wave signa. The apparatus 1000 further comprises means 1004 for suppressing an aliasing signal generated by a low clock-rate analog to digital converter in the receive signal path of a multi-downlink pipe (DLP) receiver of a millimeter wave communication device

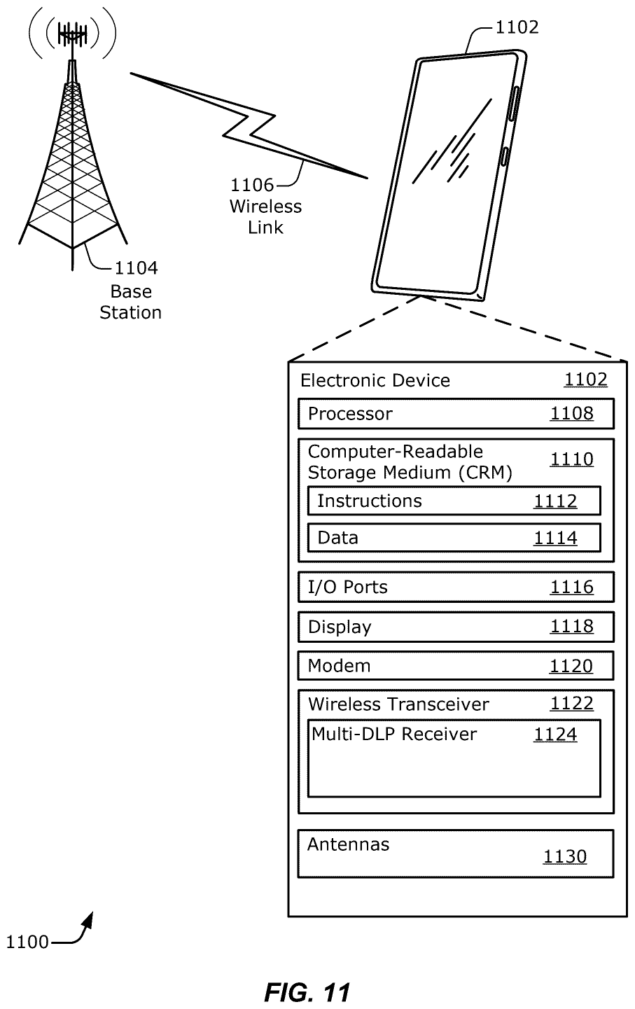

FIG. 11 is a diagram illustrating an exemplary environment 1100 that includes an electronic device 1102 and a base station 1104. The electronic device can include a transceiver (e.g., wireless transceiver 1122 of the electronic device 1102) having a filter apparatus configured in accordance with examples described herein. In some aspects, any element of a system such as the system in the environment 1100 can include a transceiver in accordance with aspects described herein. In the environment 1100, the electronic device 1102 communicates with a base station 1104 through a wireless communication link 1106 (wireless link 1106). In such an example, the electronic device 1102 is depicted as a smart phone. However, the electronic device 1102 may be implemented as any suitable computing or other electronic device, such as a cellular base station, broadband router, access point, cellular or mobile phone, gaming device, navigation device, media device, laptop computer, desktop computer, tablet computer, server, network-attached storage (NAS) device, smart appliance, vehicle-based communication system, Internet-of-Things (IoT) device, and so forth.

The base station 1104 communicates with the electronic device 1102 via the wireless link 1106, which may be implemented as any suitable type of wireless link. Although depicted as a base station tower of a cellular radio network, the base station 1104 may represent or be implemented as another device, such as a satellite, cable television head-end, terrestrial television broadcast tower, access point, peer-to-peer device, mesh network node, router, fiber optic line, another electronic device generally, and so forth. Hence, the electronic device 1102 may communicate with the base station 1104 or another device via a wired connection, a wireless connection, or a combination thereof.

The wireless link 1106 can include a downlink of data or control information communicated from the base station 1104 to the electronic device 1102 and an uplink of other data or control information communicated from the electronic device 1102 to the base station 1104. The wireless link 1106 may be implemented using any suitable communication protocol or standard, such as 3rd Generation Partnership Project Long-Term Evolution (3GPP LTE), 5G New Radio (3GPP 5GNR), IEEE 802.11, IEEE 802.16, Bluetooth™, and so forth.

The electronic device 1102 includes a processor 1108 and a computer-readable storage medium 1110 (CRM 1110). The processor 1108 may include any type of processor, such as an application processor or a multi-core processor, that is configured to execute processor-executable instructions (e.g., code) stored by the CRM 1110. The CRM 1110 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the CRM 1110 is implemented to store instructions 1112, data 1114, and other information of the electronic device 1102, and thus does not include transitory propagating signals or carrier waves.

The electronic device 1102 may also include input/output ports 1116 (I/O ports 1116) or a display 1118. The I/O ports 1116 enable data exchanges or interaction with other devices, networks, or users. The I/O ports 1116 may include serial ports (e.g., universal serial bus (USB) ports), parallel ports, audio ports, infrared (IR) ports, and so forth. The display 1118 can be realized as a screen or projection that presents graphics, e.g. one or more graphical images, of the electronic device 1102, such as for a user interface associated with an operating system, program, or application. Alternatively, or additionally, the display 1118 may be implemented as a display port or virtual interface through which graphical content of the electronic device 1102 is communicated or presented.

For communication purposes, the electronic device 1102 also includes a modem 1120, a wireless transceiver 1122, and at least one an antenna 1130. The wireless transceiver 1122 includes a multi-DLP receiver 1124 including one or more filter apparatuses in accordance with aspects described herein. Additionally, or alternatively, the electronic device 1102 may include a wired transceiver, such as an Ethernet or fiber optic interface for communicating over a personal or local network, an intranet, or the Internet. The wireless transceiver 1122 may facilitate communication over any suitable type of wireless network, such as a wireless local area network (LAN) (WLAN) such as Wi-Fi or Bluetooth, a peer-to-peer (P2P) network, a mesh network, a cellular network (e.g., 3GPP2, 4G LTE, 5G NR, or other cellular network), a wireless wide-area-network (WWAN) (e.g., based on 3GPP2, 4G LTE, 5G NR, etc.), a navigational network (e.g., the Global Positioning System (GPS) of North America or another Satellite Positioning System (SPS)), and/or a wireless personal-area-network (WPAN). In the context of the example environment 1100, the wireless transceiver 1122 enables the electronic device 1102 to communicate with the base station 1104 and networks connected therewith. Other figures referenced herein may pertain to other wireless networks.

The modem 1120, such as a baseband modem, may be implemented as a system on-chip (SoC) that provides a digital communication interface for data, voice, messaging, and other applications of the electronic device 1102. Other implementations can include other elements in accordance with the descriptions provided herein. The modem 1120 may also include baseband circuitry to perform high-rate sampling processes that can include analog-to-digital conversion (ADC), digital-to-analog conversion (DAC), gain correction, skew correction, frequency translation, and so forth. The modem 1120 may also include logic to perform in-phase/quadrature (I/Q) operations, such as synthesis, encoding, modulation, demodulation, and decoding. More generally, the modem 1120 may be realized as a digital signal processor (DSP) or a processor that is configured to perform signal processing to support communications via one or more networks. Alternatively, ADC or DAC operations may be performed by a separate component or another illustrated component, such as the wireless transceiver 1122.

The wireless transceiver 1122 can include circuitry, logic, and other hardware for transmitting or receiving a wireless signal for at least one communication frequency band. In operation, the wireless transceiver 1122 can implement at least one radio-frequency transceiver unit to process data and/or signals associated with communicating data of the electronic device 1102 via the antenna 1130. Generally, the wireless transceiver 1122 can include filters, switches, amplifiers, and so forth for routing and processing signals that are transmitted or received via the antenna 1130. Generally, the wireless transceiver 1122 includes multiple transceiver units (e.g., for different wireless protocols such as WLAN versus WWAN or for supporting different frequency bands or frequency band combinations).

The filters, switches, amplifiers, mixers, and so forth of wireless transceiver 1122 can include, in one example, at least one single-ended amplifier, switch circuitry, at least one transformer, at least one differential amplifier, and at least one mixer. In some implementations, the single-ended amplifier, which amplifies a strength of a signal, is coupled to the antenna 1130. Thus, the single-ended amplifier can couple a wireless signal to or from the antenna 1130 in addition to increasing a strength of the signal. In some implementations, the switch circuitry can switchably couple individual transformers a set of transformers to the single-ended amplifier. The set of transformers provides a physical or electrical separation between the single-ended amplifier and other circuitry of the wireless transceiver 1122. The set of transformers also conditions a signal propagating through the set of transformers. Outputs of a transformer can be coupled to one or more mixers.

Some examples can use a differential amplifier at the output of the transformer before the signal is input to a mixer. In such examples, the differential amplifier, like the single-ended amplifier, reinforces a strength of a propagating signal. The wireless transceiver can further perform frequency conversion using a synthesized signal and the mixer. The mixer may include an upconverter and/or a downconverter that performs frequency conversion in a single conversion step, or through multiple conversion steps. The wireless transceiver 1122 may also include logic (not shown) to perform in-phase/quadrature (I/Q) operations, such as synthesis, encoding, modulation, demodulation, and decoding using a synthesized signal.

In some cases, components of the wireless transceiver 1122, or a transceiver unit thereof, are implemented as separate receiver and transmitter entities. In addition, different wireless protocols such as WWAN and WLAN may be implemented on separate chips or as separate System-on-a-Chips (SoCs). As such, the blocks such as the modem 1120 and transceiver 1122 may represent more than one modem 1120 or transceiver implemented either together on separate chips or separate SoCs.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR) or corresponding mmW elements, (iv) an ASIC such as a mobile station modem (MSM), (v) a module that may be embedded within other devices, (vi) a receiver, cellular phone, wireless device, handset, or mobile unit, (vii) etc.

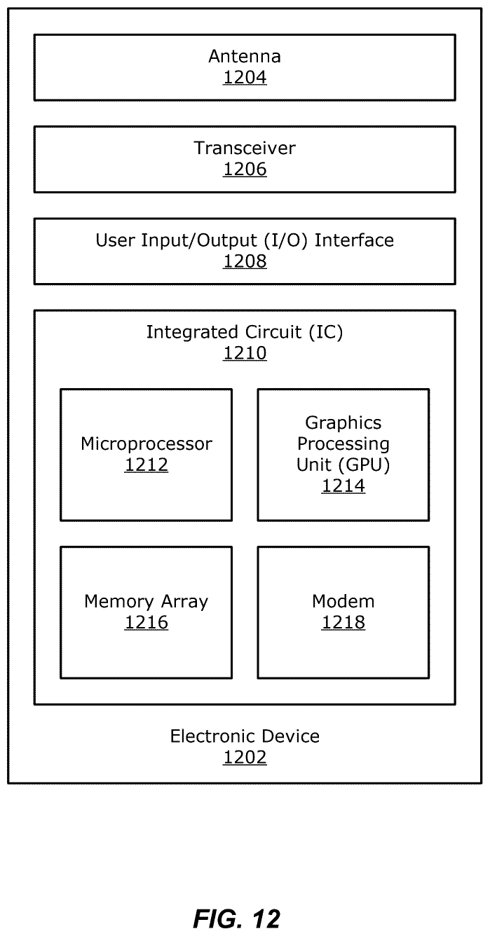

FIG. 12 is a diagram illustrating an exemplary electronic device 1202, which includes a transceiver 1206 that can include and/or implement a filter apparatus in accordance with aspects described herein. As shown, the electronic device 1202 includes an antenna 1204, a transceiver 1206, and a user input/output (I/O) interface 1208, in addition to the integrated circuit 1210. Illustrated examples of the integrated circuit 1210, or cores thereof, include a microprocessor 1212, a graphics processing unit (GPU) 1214, a memory array 1216, and a modem 1218. Each component can be operably coupled to another component, such as the GPU 1214 being operably coupled to the user I/O interface 1208.

The electronic device 1202 can be a mobile or battery-powered device or a fixed device that is designed to be powered by an electrical grid. Examples of the electronic device 1202 include a server computer, a network switch or router, a blade of a data center, a personal computer, a desktop computer, a notebook or laptop computer, a tablet computer, a smart phone, an entertainment appliance, or a wearable electronic device such as a smartwatch, intelligent glasses, or an article of clothing. An electronic device 1202 can also be a device, or a portion thereof, having embedded electronics. Examples of the electronic device 1202 with embedded electronics include a passenger vehicle, industrial equipment, a refrigerator or other home appliance, a drone or other unmanned aerial vehicle (UAV), or a power tool.

For an electronic device with a wireless capability, the electronic device 1202 includes an antenna 1204 that is coupled to a transceiver 1206 to enable reception or transmission of one or more wireless signals. The integrated circuit 1210 may be coupled to the transceiver 1206 to enable the integrated circuit 1210 to have access to received wireless signals or to provide wireless signals for transmission via the antenna 1204. The electronic device 1202 as shown also includes at least one user I/O interface 1208. Examples of the user I/O interface 1208 include a keyboard, a mouse, a microphone, a touch-sensitive screen, a camera, an accelerometer, a haptic mechanism, a speaker, a display screen, or a projector.

The integrated circuit 1210 may comprise, for example, one or more instances of a microprocessor 1212, a GPU 1214, a memory array 1216, a modem 1218, and so forth. The microprocessor 1212 may function as a central processing unit (CPU) or other general-purpose processor. Some microprocessors include different parts, such as multiple processing cores, that may be individually powered on or off. The GPU 1214 may be especially adapted to process visual related data for display, such as video data images. If visual-related data is not being rendered or otherwise processed, the GPU 1214 may be fully or partially powered down. The memory array 1216 stores data for the microprocessor 1212 or the GPU 1214. Example types of memory for the memory array 1216 include random access memory (RAM), such as dynamic RAM (DRAM) or static RAM (SRAM); flash memory; and so forth. If programs are not accessing data stored in memory, the memory array 1216 may be powered down overall or block-by-block. The modem 1218 demodulates a signal to extract encoded information or modulates a signal to encode information into the signal. If there is no information to decode from an inbound communication or to encode for an outbound communication, the modem 1218 may be idled to reduce power consumption. The integrated circuit 1210 may include additional or alternative parts than those that are shown, such as an I/O interface, a sensor such as an accelerometer, a transceiver or another part of a receiver chain, a customized or hard-coded processor such as an application-specific integrated circuit (ASIC), and so forth.

The integrated circuit 1210 may also comprise a system on chip (SoC). An SoC may integrate a sufficient number of different types of components to enable the SoC to provide computational functionality as a notebook computer, a mobile phone, or another electronic apparatus using one chip, at least primarily. Components of an SoC, or an integrated circuit 1210 generally, may be termed cores or circuit blocks. Examples of cores or circuit blocks include, in addition to those that are illustrated in FIG. 12, a voltage regulator, a main memory or cache memory block, a memory controller, a general-purpose processor, a cryptographic processor, a video or image processor, a vector processor, a radio, an interface or communications subsystem, a wireless controller, or a display controller. Any of these cores or circuit blocks, such as a central processing unit or a multimedia processor, may further include multiple internal cores or circuit blocks.

Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, smart glasses, augmented reality (AR) glasses, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, such as a vehicular head unit, avionics systems, a drone, and a multicopter.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

Although selected aspects have been illustrated and described in detail, it will be understood that various substitutions and alterations may be made therein without departing from the spirit and scope of the present invention, as defined by the following claims.

Illustrative aspects of the present disclosure include, but are not limited to:

Aspect 1. A filter apparatus comprising: a signal input node; a signal output; an amplifier having an amplifier output, a negative input, and a positive input, wherein the positive input is coupled to a reference voltage, and wherein the amplifier output is coupled to the signal output; and a twin-T network in a feedback path coupled from the amplifier output to the negative input, wherein the twin-T network comprises a first capacitor and a second capacitor serially coupled between the amplifier output and the negative input of the amplifier, wherein the first capacitor and the second capacitor are connected via a first node, and wherein the signal input node is coupled to the first node.

Aspect 2. The filter apparatus of Aspect 1, wherein the twin-T network further comprises: a first resistor and a second resistor serially coupled between the amplifier output and the negative input of the amplifier, wherein the first resistor and the second resistor are connected via a second node, wherein the signal input node is coupled to the second node, and wherein the second node is coupled to a reference node via a third capacitor.

Aspect 3. The filter apparatus of Aspect 2, wherein the signal input node is coupled to the first node via a third capacitor, wherein the signal input node is coupled to the second node via a third resistor, and wherein the second node is coupled to a reference node via a fourth capacitor.

Aspect 4. The filter apparatus of Aspect 3, further comprising a fourth resistor coupled in parallel across the first capacitor.

Aspect 5. The filter apparatus of Aspect 4, further comprising high frequency real pole circuitry coupled to the signal input node.

Aspect 6. The filter apparatus of Aspect 5, wherein the high frequency real pole circuitry comprises: a fifth resistor coupled between a second input node and the signal input node; a fifth capacitor coupled between the signal input node and the reference node; and the fourth capacitor.

Aspect 7. The filter apparatus of Aspect 6, further comprising a plurality of switches in the feedback path configurable for multiple operational configurations.

Aspect 8. The filter apparatus of Aspect 7, wherein the multiple operational configurations comprise a Rauch filter configuration and a Rauch filter with a transmission zero filter configuration.

Aspect 9. The filter apparatus of Aspect 8, wherein the multiple operational configurations further comprise a programmable gain amplifier (PGA) configuration.

Aspect 10. The filter apparatus of Aspect 9, wherein the plurality of switches comprise: a first switch coupled between the signal input node and the third capacitor; a second switch coupled between the signal input node and the fifth resistor; a third switch coupled between the fourth capacitor and a node between the second resistor and the third resistor; a fourth switch coupled between the first resistor and the node between the second resistor and the third resistor; a fifth switch coupled between the negative input and the second capacitor; a sixth switch coupled between the second capacitor and the fourth resistor; a seventh switch coupled between the negative input and the fourth resistor; an eighth switch coupled between the second capacitor and the first capacitor; and a ninth switch coupled between the negative input and the first capacitor.

Aspect 11. The filter apparatus of Aspect 10, wherein control circuitry coupled to the plurality of switches closes the second switch, the seventh switch, and the ninth switch, and opens the first, third, fourth, fifth, sixth, and eighth switches for the PGA configuration.

Aspect 12. The filter apparatus of Aspect 11, wherein the control circuitry closes the third, fourth, and ninth switches and opens the first, second, third, fifth, sixth, seventh, and eighth switches for the Rauch filter configuration.

Aspect 13. The filter apparatus of Aspect 12, wherein the control circuitry closes the first, third fourth, fifth, seventh, and ninth switches and opens the second, sixth, and eighth switches for the Rauch filter with the transmission zero filter configuration.

Aspect 14. The filter apparatus of any of Aspects 10 through 13, further comprising high frequency real pole circuitry coupled to the signal input node.

Aspect 15. The filter apparatus of Aspect 14, wherein the high frequency real pole circuitry comprises: an input resistor coupled between a second input node and the signal input node; a fifth capacitor coupled between the signal input node and the reference node; and the fourth capacitor.

Aspect 16. The filter apparatus of Aspect 15, wherein the plurality of switches further comprises a tenth switch coupled between the fifth capacitor and the signal input node, wherein the tenth switch enables and disables the high frequency real pole circuitry.

Aspect 17. The filter apparatus of any of Aspects 1 through 15, wherein the filter apparatus comprises a baseband filter in a receive signal path for a downconverted millimeter wave (mmW) signal.

Aspect 18. A filter apparatus comprising: means for filtering a baseband signal in a receive signal path for a downconverted millimeter wave signal; and means for suppressing an aliasing signal generated by a low clock-rate analog to digital converter in the receive signal path of a multi-downlink pipe (DLP) receiver of a millimeter wave communication device.

Aspect 19. A method of operating a wireless communication device, the method comprising: receiving a wireless millimeter wave communication signal; downconverting the wireless millimeter wave communication signal to a baseband communication signal; filtering the baseband communication signal using a filter apparatus comprising a twin-T network in a feedback path with notch rejection at aliasing frequencies associated with a low clock-rate analog to digital converter to generate a filtered baseband communication signal; and converting the filtered baseband communication signal to a digital signal using the low clock-rate analog to digital converter.

Aspect 20. The method of Aspect 19, wherein the twin-T network further comprises: a first resistor and a second resistor serially coupled between the amplifier output and the negative input of the amplifier, wherein the first resistor and the second resistor are connected via a second node, wherein the signal input node is coupled to the second node, and wherein the second node is coupled to a reference node via a third capacitor.

Aspect 21. Means for filtering signals in a receiver in accordance with any aspect described above.

What is claimed is:

1. A filter apparatus comprising:
a signal input node;
a signal output;
an amplifier having an amplifier output, a negative input, and a positive input, wherein the positive input is coupled to a reference voltage, and wherein the amplifier output is coupled to the signal output; and
a twin-T network in a feedback path coupled from the amplifier output to the negative input, wherein the twin-T network comprises a first capacitor and a second capacitor serially coupled between the amplifier output and the negative input of the amplifier, wherein the first capacitor and the second capacitor are connected via a first node, and wherein the signal input node is coupled to the first node.

2. The filter apparatus of claim 1, wherein the twin-T network further comprises:
a first resistor and a second resistor serially coupled between the amplifier output and the negative input of the amplifier, wherein the first resistor and the second resistor are connected via a second node, wherein the signal input node is coupled to the second node, and wherein the second node is coupled to a reference node via a fourth capacitor.

3. The filter apparatus of claim 2, wherein the signal input node is coupled to the first node via a third capacitor, wherein the signal input node is coupled to the second node via a third resistor.

4. The filter apparatus of claim 3, further comprising a fourth resistor coupled in parallel across the first capacitor.

5. The filter apparatus of claim 4, further comprising high frequency real pole circuitry coupled to the signal input node.

6. The filter apparatus of claim 5, wherein the high frequency real pole circuitry comprises:
a fifth resistor coupled between a second input node and the signal input node;
a fifth capacitor coupled between the signal input node and the reference node; and
the fourth capacitor.

7. The filter apparatus of claim 6, further comprising a plurality of switches in the feedback path configurable for multiple operational configurations.

8. The filter apparatus of claim 7, wherein the multiple operational configurations comprise a Rauch filter configuration and a Rauch filter with a transmission zero filter configuration.

9. The filter apparatus of claim 8, wherein the multiple operational configurations further comprise a programmable gain amplifier (PGA) configuration.

10. The filter apparatus of claim 9, wherein the plurality of switches comprise:
a first switch coupled between the signal input node and the third capacitor;
a second switch coupled between the signal input node and the fifth resistor;
a third switch coupled between the fourth capacitor and a node between the second resistor and the third resistor;
a fourth switch coupled between the first resistor and the node between the second resistor and the third resistor;
a fifth switch coupled between the negative input and the second capacitor;
a sixth switch coupled between the second capacitor and the fourth resistor;
a seventh switch coupled between the negative input and the fourth resistor;
an eighth switch coupled between the second capacitor and the first capacitor; and
a ninth switch coupled between the negative input and the first capacitor.

11. The filter apparatus of claim 10, wherein control circuitry coupled to the plurality of switches closes the second switch, the seventh switch, and the ninth switch, and opens the first, third, fourth, fifth, sixth, and eighth switches for the PGA configuration.

12. The filter apparatus of claim 11, wherein the control circuitry closes the third, fourth, and ninth switches and opens the first, second, third, fifth, sixth, seventh, and eighth switches for the Rauch filter configuration.

13. The filter apparatus of claim 12, wherein the control circuitry closes the first, third fourth, fifth, seventh, and ninth switches and opens the second, sixth, and eighth switches for the Rauch filter with the transmission zero filter configuration.

14. The filter apparatus of claim 1, further comprising high frequency real pole circuitry coupled to the signal input node.

15. The filter apparatus of claim 14, wherein the high frequency real pole circuitry comprises:
an input resistor coupled between a second input node and the signal input node; and
a fifth capacitor coupled between the signal input node and a reference node.

16. The filter apparatus of claim 15, further comprising a tenth switch coupled between the fifth capacitor and the signal input node, wherein the tenth switch enables and disables the high frequency real pole circuitry.

17. The filter apparatus of claim 1, wherein the filter apparatus comprises a baseband filter in a receive signal path for a downconverted millimeter wave (mmW) signal.

18. A filter apparatus comprising:
means for filtering a baseband signal in a receive signal path for a downconverted millimeter wave signal; and
means for suppressing an aliasing signal generated by a low clock-rate analog to digital converter in the receive signal path of a multi-downlink pipe (DLP) receiver of a millimeter wave communication device.

19. A method of operating a wireless communication device, the method comprising:
receiving a wireless millimeter wave communication signal;
downconverting the wireless millimeter wave communication signal to a baseband communication signal;
filtering the baseband communication signal using a filter apparatus comprising a twin-T network in a feedback path with notch rejection at aliasing frequencies associated with a low clock-rate analog to digital converter to generate a filtered baseband communication signal; and
converting the filtered baseband communication signal to a digital signal using the low clock-rate analog to digital converter.

20. The method of claim 19, wherein the filter apparatus comprises a signal input node, a signal output, an amplifier having an amplifier output, a negative input, and a positive input, wherein the positive input is coupled to a reference voltage, and wherein the amplifier output is coupled to the signal output, and the twin-T network in the feedback path coupled from the amplifier output to the negative input, wherein the twin-T network comprises a first capacitor and a second capacitor serially coupled between the amplifier output and the negative input of the amplifier, wherein the first capacitor and the second capacitor are connected via a first node, and wherein the signal input node is coupled to the first node; and
wherein the twin-T network further comprises:
a first resistor and a second resistor serially coupled between the amplifier output and the negative input of the amplifier, wherein the first resistor and the second resistor are connected via a second node, wherein the signal input node is coupled to the second node, and wherein the second node is coupled to a reference node via a third capacitor.
